(19) United States
(12) Patent Application Publication
(10) Pub. No.: US 2024/0419466 A1
(43) Pub. Date: Dec. 19, 2024

(54) SPEED SENSOR EMULATOR FOR HARDWARE IN THE LOOP

(71) Applicant: DANA ITALIA S.R.L., Arco (IT)

(72) Inventors: Bruno DALVIT, Arco (IT); Francesco MARCHETTI, Mirano (IT); Matteo COCETTI, Arco (IT)

(21) Appl. No.: 18/336,667

(22) Filed: Jun. 16, 2023

(51) Int. Cl. G06F 9/455

(52) U.S. Cl. CPC G06F 9/455

(57) ABSTRACT

Methods and systems for emulating a speed sensor with current output via a hardware-in-the-loop (HIL) system are described. In one example, the HIL system outputs a voltage signal that is converted into two current signals that may be interpreted into speed and direction information. The current output may decrease signal sensitivity to electrical noise.

### TECHNICAL FIELD

The present disclosure relates to a method and system for simulating a speed sensor with current output. The speed sensor may provide feedback of a speed of an internal combustion engine, electric machine, wheel, sprocket, or other rotating device.

### BACKGROUND AND SUMMARY

A hardware-in-the-loop (HIL) system may interface with a controller (e.g., a vehicle system controller, engine controller, electric machine controller, brake system controller, etc.) and the HIL system may emulate sensors, actuators, and other devices that interface with the controller when the controller is deployed in a system. The HIL system may receive inputs from the controller and provide outputs to the controller as part of a process to evaluate the controller. One type of output the HIL system may provide to a controller that is operating as a device under test is an emulated speed signal that is generated as an output voltage from the HIL system. While sensors that output a voltage may be effective for some systems, they may be less effective in other systems, such as systems that create higher levels of electrical noise. Sensors that output a voltage level may give way to other sensors that are less prone to being influenced by electrical noise. Therefore, it may be desirable for a HIL system to emulate other types of speed sensors that may be influenced less by electrical noise.

The inventors herein have recognized the above-mentioned issues and have developed a sensor emulation system, comprising: a first flip-flop configured to receive a signal at a clock input of the first flip-flop and provide a first voltage output to a first voltage controlled current source; and a second flip-flop configured to receive an inverse of the signal at a clock input of the second flip-flop and provide a second voltage output to a second voltage controlled current source.

By generating a signal via a HIL system and inputting the signal into two flip-flops that drive voltage controlled current sources, it may be possible to provide the technical result of emulating a current output of a speed sensor. Specifically, the HIL system may generate a pulse width modulated signal via a digital output and the signal and the inverse of the signal may be input to the two flip-flops. The flip-flops may generate a first signal and a second signal, the second signal out of phase with the first signal. The first and second signals may provide input to two voltage controlled current sources and the two voltage controlled current sources may be electrically coupled to a device under test.

The present description may provide several advantages. In particular, the approach may enable reliable emulation of a speed sensor with current output. In addition, the approach may allow a HIL system to emulate a speed sensor with current output at a lower financial cost. Further, the approach may be applied to single wire sensors that have direction of rotation of a device coded into a duty cycle of an output signal.

It may be understood that the summary above is provided to introduce in simplified form a selection of concepts that are further described in the detailed description. It is not meant to identify key or essential features of the claimed subject matter, the scope of which is defined uniquely by the claims that follow the detailed description. Furthermore, the claimed subject matter is not limited to implementations that solve any disadvantages noted above or in any part of this disclosure.

### BRIEF DESCRIPTION OF THE DRAWINGS

The accompanying drawings are incorporated herein as part of the specification. The drawings described herein illustrate embodiments of the presently disclosed subject matter, and are illustrative of selected principles and teachings of the present disclosure. However, the drawings do not illustrate all possible implementations of the presently disclosed subject matter, and are not intended to limit the scope of the present disclosure in any way.

FIG. 1 is a schematic diagram of a vehicle with controller and wheel speed sensors;

FIG. 2 shows a block diagram of an example HIL system that is coupled to the controller of FIG. 1;

FIG. 3 shows an example circuit for emulating a speed sensor with current output;

FIG. 4 shows a truth table for a D flip-flop;

FIG. 5 shows a speed sensor and rotational directional examples;

FIG. 6 shows signal outputs for the circuit of FIG. 3;

FIG. 7 shows an example of simulating a direction change for a monitored wheel or shaft;

FIGS. 8 and 9 show an example state machine for emulating a speed sensor with current output; and

FIGS. 10-12 show example sequences for emulating degradation of a speed sensor.

### DETAILED DESCRIPTION

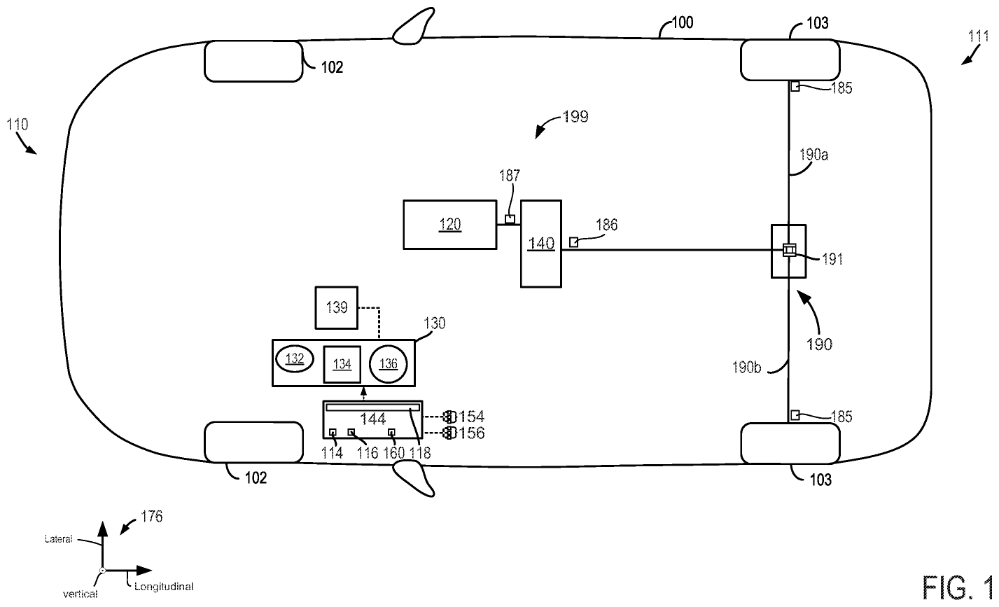

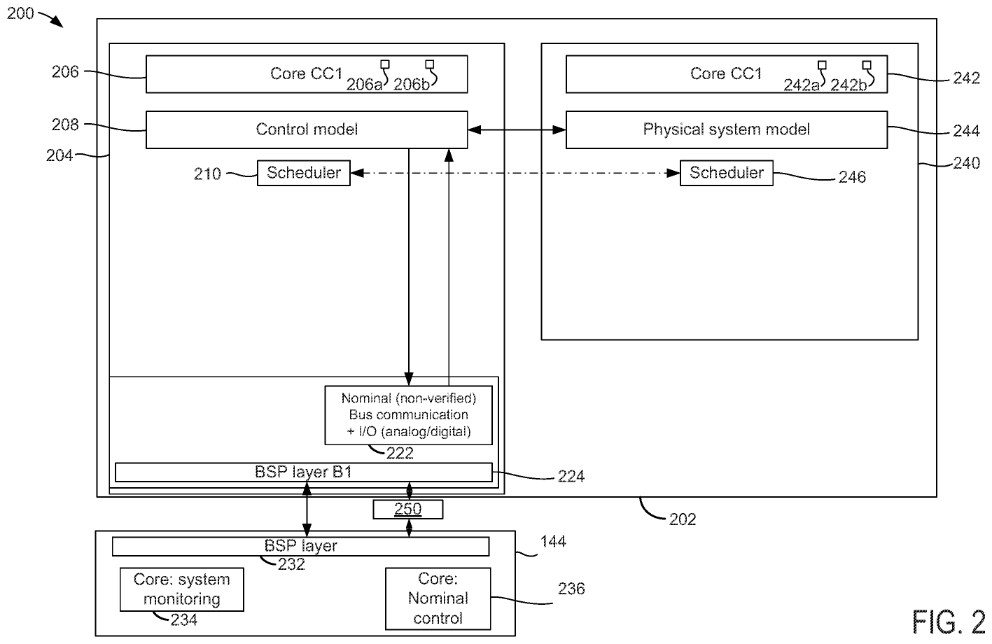

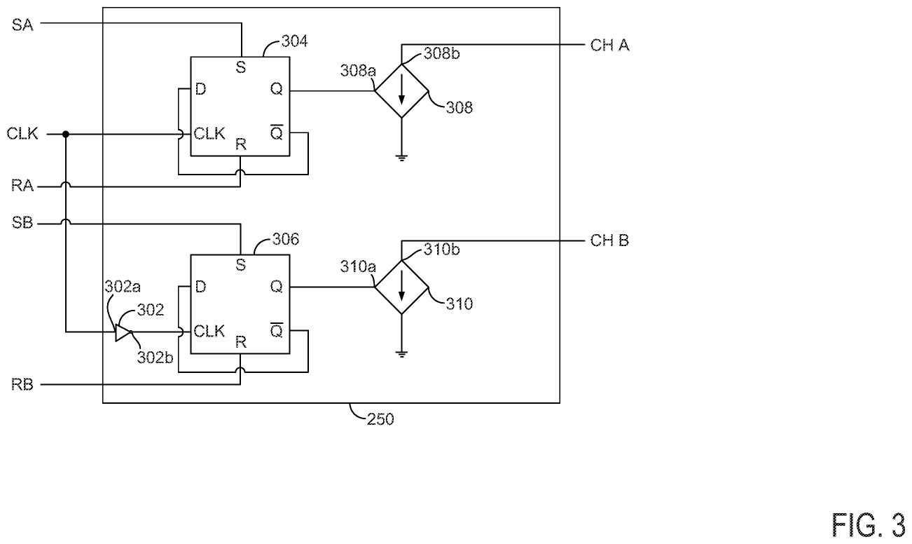

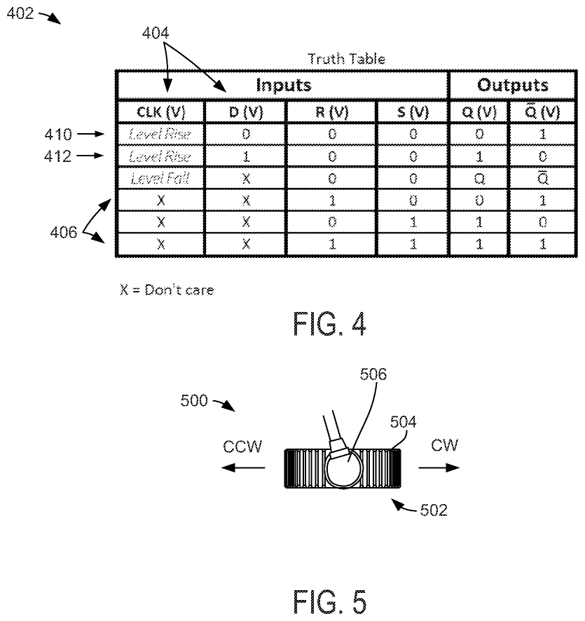

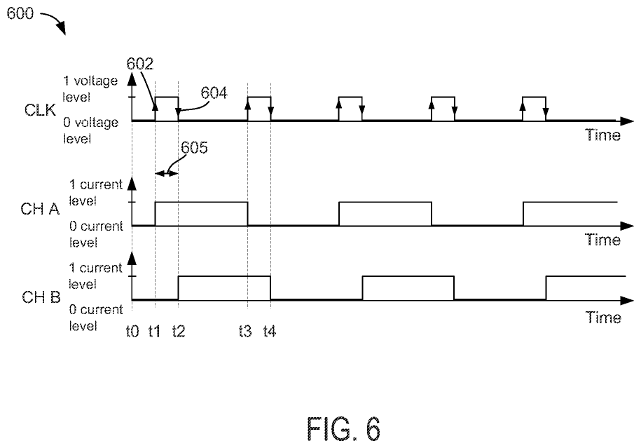

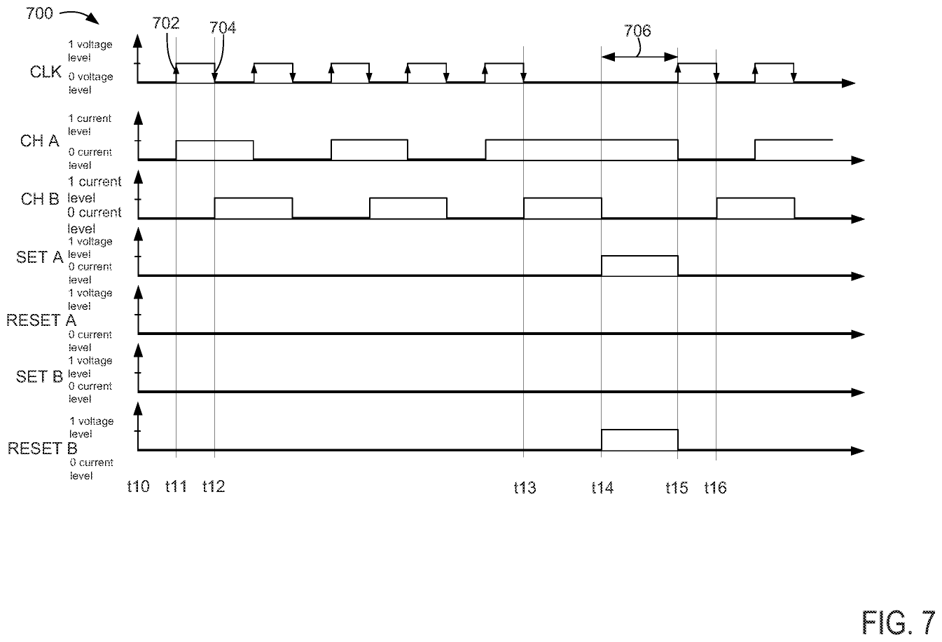

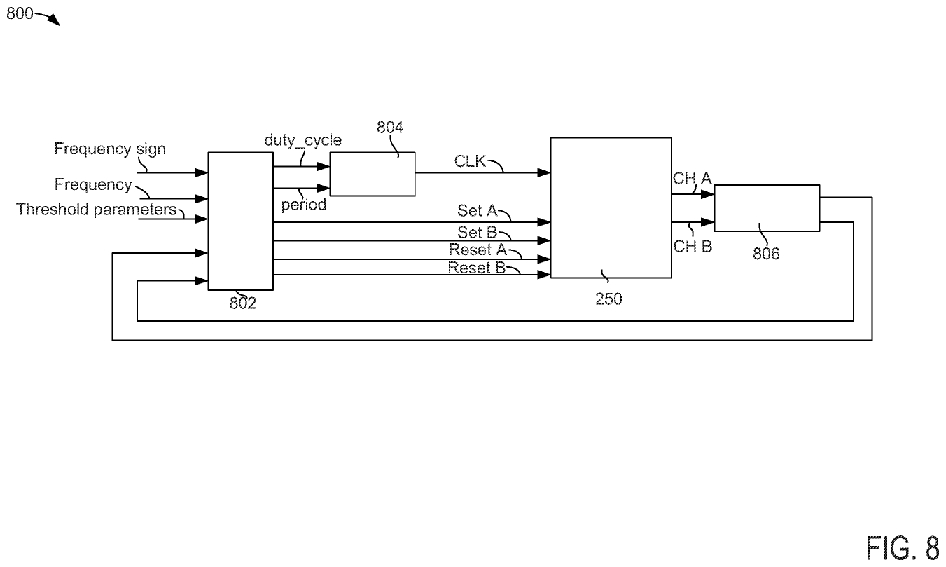

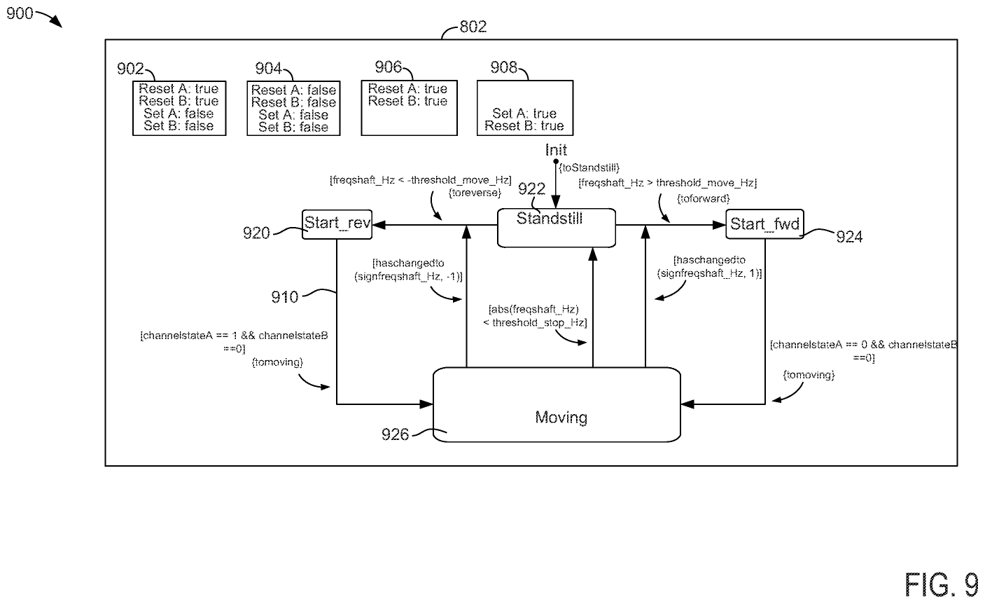

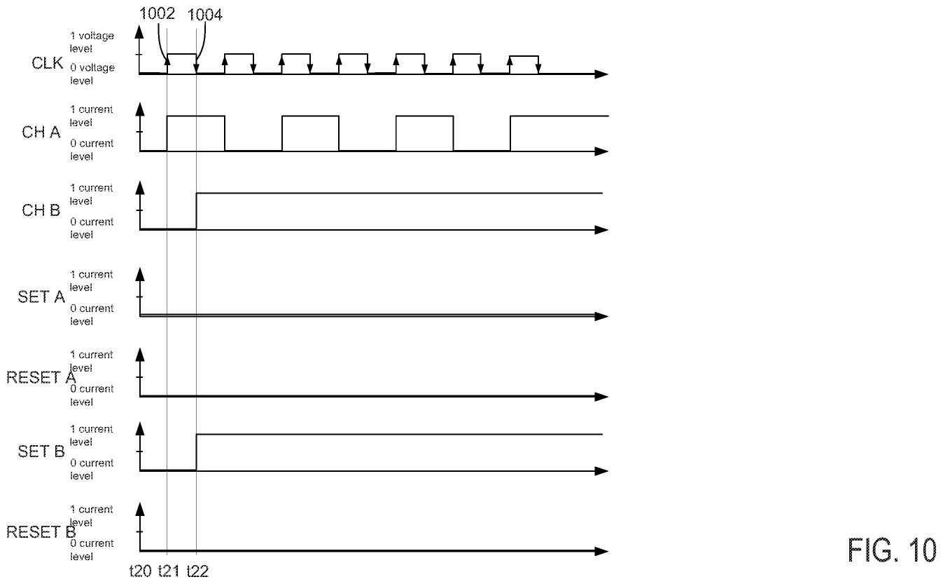

The following description relates to systems and methods for emulating a speed sensor with current output via a HIL system. In one example, the HIL outputs a pulse width modulated signal via a digital voltage output and the digital voltage output is converted into two current outputs to reduce influence that may be associated with electrical noise sources (e.g., switching transistors of an inverter, etc.). The HIL system and speed sensor emulation may be applied to evaluate components and systems of a vehicle of the type shown in FIG. 1. The HIL system may be configured as shown in FIG. 2. The HIL system may include or may be modified to interface with a speed sensor with current output emulator circuit as shown in FIG. 3. Flip-flops of the emulation circuit may operate as shown in the truth table of FIG. 4. The emulation circuit may mimic the operation of a speed sensor as shown in FIG. 5. The emulation circuit may function as shown in FIGS. 6 and 7. The emulation circuit and HIL system may be operated according to the state machine of FIGS. 8 and 9. The emulation circuit and HIL system may also simulate speed sensor degradation as shown in FIGS. 10-12.

It is to be understood that the present disclosure may assume various alternative orientations and step sequences, except where expressly specified to the contrary. It is also to be understood that the specific devices and processes illustrated in the attached drawings, and described in the specification are simply exemplary embodiments of the inventive concepts disclosed herein. Therefore, specific dimensions, directions or other physical characteristics relating to the various embodiments disclosed are not to be considered as limiting, unless expressly stated otherwise.

It is within the scope of this disclosure, and as a non-limiting example, that the method and system for a HIL system may be applied in automotive, off-road vehicle, all-terrain vehicle, construction, and structural applications. As a non-limiting example, the method and system for building and operating a HIL system disclosed herein may also be used for evaluating control systems of passenger vehicles, electric vehicles, hybrid vehicles, commercial vehicles, and autonomous vehicles.

FIG. 1 illustrates an example vehicle driveline 199 included in vehicle 100. Mechanical connections are shown in FIG. 1 as solid lines and electrical connections are indicated as dashed lines.

Vehicle 100 includes a front side 110 and a rear side 111. Vehicle 100 includes front wheels 102 and rear wheels 103. In this example, vehicle 100 is configured as a two wheel drive vehicle; however, in other examples, vehicle 100 may be configured as a four wheel drive vehicle. Vehicle 100 includes a propulsion source 120 that may selectively provide propulsive effort to rear axle 190 and front axle 101. Propulsion source 120 may be an internal combustion engine (e.g., spark ignited or diesel), or alternatively, propulsion source 120 may be an electric machine (e.g., a motor/generator), or a combination thereof. Propulsion source 120 is shown mechanically coupled to gearbox 140, and gearbox 140 is mechanically coupled to rear axle 190. Propulsion source 120 may provide mechanical power to gearbox 140. Rear axle 190 may receive mechanical power from gearbox 140 so that mechanical power may be transmitted to rear wheels 103.

Rear axle 190 comprises two half shafts, including a first or right half shaft 190a and a second or left half shaft 190b. The rear axle 190 may be an integrated axle that includes a differential gear set 191. Differential gear set 191 may be open when vehicle 100 is traveling on roads and negotiating curves so that a right rear wheel may rotate at a different speed than a left rear wheel. Differential gear set 191 allows vehicle 100 to turn without dragging a right rear wheel or a left rear wheel.

Vehicle 100 includes controller 144 and controller 144 includes read-only memory (ROM or non-transitory memory) 114, random access memory (RAM) 116, a digital processor or central processing unit (CPU) 160, and inputs and outputs (I/O) 118 (e.g., digital inputs including counters, timers, and discrete inputs, digital outputs, analog inputs, and analog outputs). Controller 144 may receive signals from sensors 154 (including transmission output shaft speed sensors 186, propulsion source temperature sensors, wheel speed sensors 185, propulsion source speed sensors 187, etc.) and provide control signal outputs to actuators 156 (including propulsion source torque actuators, axle locking actuators, etc.). Controller 144 may communicate with dashboard 130, propulsion source 120, external controllers, external servers, and other controllers where present.

Vehicle 100 may also include a dashboard 130 that a human operator of the vehicle may interact with. Dashboard 130 may include an interactive navigation system 134 that generates and displays trip routes responsive to user input. Dashboard 130 may further include a display system 132 configured to display information to the vehicle operator. Display system 132 may comprise, as a non-limiting example, a touchscreen, or human machine interface (HMI), display which enables the vehicle operator to view graphical information as well as input commands. In some examples, display system 132 may be connected wirelessly to the internet (not shown) via controller 144. As such, in some examples, the vehicle operator may communicate via display system 132 with an internet site or software application (app) and controller 144. Dashboard 130 and devices included therein may be supplied with electrical power via battery 139. Battery 139 may also supply power to controller 144 and a starter motor (not shown) for propulsion source 120.

Dashboard 130 may further include an operator interface 136 via which the vehicle operator may adjust the operating status of the vehicle. Specifically, the operator interface 136 may be configured to initiate and/or terminate operation of the vehicle driveline (e.g., propulsion source 120) based on an operator input. Various examples of the operator interface 136 may include interfaces that utilize a physical apparatus, such as an active key, that may be inserted into the operator interface 136 to activate the propulsion source 120 and to turn on the vehicle 100, or may be removed to shut down the propulsion source 120 and to turn off the vehicle. Spatial orientation of vehicle 100 and vehicle axis are indicated via axes 176.

Turning now to FIG. 2, a block diagram 200 that includes a HIL system 202 for evaluating real-time control is shown. In this example, a controller 144 is electrically coupled to HIL system 202 for the purpose of evaluating whether or not controller 144 meets real-time control standards and objectives.

The HIL system 202 includes a first simulation model 204 that is comprised of a first computer core (e.g., computer processor) 206 including random access memory 206a and read-only memory 206b. The first simulation model 204 and the first computer core 206 may be associated with one or more modules (e.g., 208, 210, 222, and 224). The modules (e.g., 208, 210, 222, and 224) may be comprised of software (e.g., executable code) and/or hardware.

The modules of first simulation model 204 include a control model 208, a scheduler 210, a nominal bus communication channel 222, and a BSP layer module 224. The HIL system 202 includes a real-time operating system that schedules control model 208 (e.g., a first model) and physical system model 244 (e.g., a second model). The HIL system 202 may be applied to validate that the device under test (e.g., controller 144) conforms to its operating specifications. The control model 208 of the HIL system 202 is tasked to verify that the device under test meets its operating specifications, but execution of the physical model algorithm 244 may not interfere with the real-time operation of the control model 208 so that a useful verification of the device under test may be achieved.

The first simulation model 204 may communicate with the device under test via a board support package (BSP) layer 224 that may include software device drivers. The BSP layer 224 may include a controller area network (CAN) bus and analog signals. The BSP layer 224 interfaces solely with the control model 208. The BSP layer 224 provides realization of external access from control model 208 to the device under test (e.g., controller 144). The control model 208 is executed according to a trigger signal that is provided via scheduler 210. The control model 208 may perform a variety of functions or actions including but not limited to simulating a controller (e.g., a transmission or engine controller), organize input and output data, and exchange data with the physical system model 244. The control model 208 may facilitate exchange of digital and analog signals between the HIL system 202 and the controller 144.

The HIL system 202 also includes a second simulation model 240 that is comprised of a second computer core 242 including random access memory 242a and read-only memory 242b. The second simulation model 240 and the second computer core 242 may be associated with one or more modules (e.g., 244-246). The modules (e.g., 204-224) may be comprised of software (e.g., executable code) and/or hardware.

The modules of second simulation model 240 include a physical system module 244 and a scheduler 246. The physical system module 244 may be an algorithm that models a physical system. The algorithm may be as simple as a lookup table that is referenced by one or more inputs (e.g., driver demand) and outputs an operating state of a physical system (e.g., engine torque). Alternatively, the algorithm may include many inputs that are processed via a linear or non-linear model and the model generates outputs to simulate the physical system.

Controller 144 is shown with a BSP layer 232 and a system monitoring section 234. System monitoring module 234 may be included in a second computer core of controller 144. Controller 144 also includes a nominal control module 236 that is included in a first computer core of controller 144.

In this example, a speed sensor emulation circuit 250 is provided that is external to HIL system 200, but in other examples, emulation circuit 250 may be integrated into HIL system 200. Speed sensor emulation circuit 250 may be configured as shown in greater detail in FIG. 3. The speed sensor emulation circuit 250 may receive a digital voltage signal (e.g., a signal that carries data or information that is a function of a voltage level or value of the signal) from HIL system 200 and output a current signal (e.g., a signal that carries data or information that is a function of a current level or value of the signal) to controller 114.

Referring now to FIG. 3, an example speed sensor emulation circuit 250 for a HIL system is shown. Speed sensor emulation circuit 250 is configured to mimic operation of a speed sensor that may monitor and indicate a speed of a wheel, sprocket, shaft, or other rotating device. The speed sensor being mimicked may be configured with a current output. A current output may be desirable in systems where electrical noise and electromagnetic noise may influence sensors that output a voltage. Speed sensors with current output may control current in a current loop (e.g., a wire that stretches from the speed sensor to a sensing circuit and returns to the speed sensor) to provide a higher signal to noise ratio. Since the circuit is a single loop circuit, current flow at the sensor is substantially equal to current flow at the receiver (e.g., controller 114), thereby providing a better signal to noise ratio.

In this example, speed sensor emulation circuit 250 includes two output channels CH A and CH B. Each of the output channels outputs a pulse width modulated current output as shown in FIGS. 6 and 7. Output of the two channels may be a basis for determining if the device being monitored (e.g., wheel, shaft, sprocket, etc.) is rotating in a clockwise or counter clockwise direction. The sensor emulation circuit 250 is comprised of a first D flip-flop 304, a second D flip-flop, a first voltage controlled current source 308, a second voltage controlled current source 310, and an inverter 302.

The speed sensor emulation circuit 250 also includes several inputs SA (first D flip-flop set input), SB (second D flip-flop set input), RA (first D flip-flop reset input), RB (second D flip-flop reset input), and CLK AB (clock input). The first flip-flop 304 includes a set input(S), a reset input (R), a clock input (CLK), a data (D) input, a first output (Q) output, and a second (Q) output. The output Q̅ is the inverse of the output Q output. Similarly, the second flip-flop 306 includes a set input(S), a reset input (R), a clock input (CLK), a data (D) input, a first output (Q) output, and a second (Q) output. The output Q̅ of each D flip-flop is electrically coupled directly to its D input. The circuit input SA is directly electrically coupled to the S input of first flip-flop 304. The circuit input SB is directly electrically coupled to the S input of second flip-flop 306. The circuit input RA is directly electrically coupled to the R input of first flip-flop 304. The circuit input RB is directly electrically coupled to the R input of second flip-flop 306. The circuit output Q of first flip-flop 304 is directly electrically coupled input 308a of voltage controlled current source 308. The output 308b of voltage controlled current source 308 is directly electrically coupled to the output CH A. The circuit output Q of second flip-flop 306 is directly electrically coupled input 310a of voltage controlled current source 310. The output 310b of voltage controlled current source 310 is directly electrically coupled to the output CH B. The clock input CLK AB is directly electrically coupled to clock input CLK of first flip-flop 304 and input 302a of inverter 302. The output 302b of inverter 302 is input to the clock input CLK of second flip-flop 306. The first flip-flop 304 and the second flip-flop 306 may operate as shown in the truth table of FIG. 4 and the sequences of FIGS. 6 and 7.

The system of FIGS. 1-3 provides for a sensor emulation system, comprising: a first memory device configured to receive a signal at a clock input of the first memory device and provide a first voltage output to a first voltage controlled current source; and a second memory device configured to receive an inverse of the signal at a clock input of the second memory device and provide a second voltage output to a second voltage controlled current source. In a first example, the sensor emulation system includes where the first memory device and the second memory device are D memory device. In a second example that may include the first example, the sensor emulation system includes where the first memory device includes a first D input and a first Q̅ output. In a third example that may include one or both of the first and second examples, the sensor emulation system includes where the second memory device includes a second D input and a second Q̅ output. In a fourth example that may include one or more of the first through third examples, the sensor emulation system includes where the first Q̅ output is electrically coupled to the first D input. In a fifth example that may include one or more of the first through fourth examples, the sensor emulation system includes where the second Q̅ output is electrically coupled to the second D input. In a sixth example that may include one or more of the first through fifth examples, the sensor emulation system further comprises a first S input and a first R input on the first memory device and a second S input and a second R input on the second memory device. In a seventh example that may include one or more of the first through sixth examples, the sensor emulation system includes where a hardware-in-the-loop system generates the signal and includes outputs coupled to the first S input, the first R input, the second S input, and the second R input.

The system of FIGS. 1-3 also provides for a hardware-in-the-loop (HIL) system with sensor emulation, comprising: a HIL system coupled to a device under test; a first memory device configured to receive a signal from the HIL system at a clock input of the first memory device and provide a first voltage output to a first voltage controlled current source; and a second memory device configured to receive an inverse of the signal at a clock input of the second memory device and provide a second voltage output to a second voltage controlled current source. In a first example, the HIL system further comprises a device under test coupled to the system. In a second example that may include the first example, the HIL system further comprises a first digital output of the HIL system generating the signal and additional digital outputs of the HIL system generating output to a first memory device S input, a first memory device R input, a second memory device S input, and a second memory device R input. In a third example that may include one or both of the first and second examples, the HIL system includes where the first voltage controlled current source is coupled to the device under test. In a fourth example that may include one or both of the first through third examples, the HIL system includes where the second voltage controlled current source is coupled to the device under test.

Moving on to FIG. 4, an example truth table 402 for the D flip-flops of FIG. 3 is shown. Truth table 402 is arranged into rows 406 and columns 404. The columns include columns for inputs (CLK, D. R. S) and outputs (Q and Q). The rows include space for inputs to the various flip-flop inputs and outputs. The entry “Level Rise” pertains to a condition where a signal supplied to the clock input CLK of the flip-flop transitions from a lower voltage (e.g., zero volts) to a higher voltage (e.g., 5 volts). The entry “Level Fall” pertains to a condition where the signal supplied to the clock input CLK of the flip-flop transitions from a higher voltage to a lower voltage. The higher voltage may also be referred to as a logical 1 or true and the lower voltage may be referred to as a logical 0 or false. The entry “X” indicates “don't care” so that the input may be a logical 0, logical 1, or other value that has no effect on flip-flop output.

Truth table 402 may be read as follows: the first row 410 indicates that output Q will be a logical 0 (false) and output Q̅ will be a logical 1 (True) when the logical zero level voltages are input to the D, R, and S inputs of the flip-flop when the signal input to the clock input (CLK) transitions from a low level (e.g., 0) to a high level (e.g., 1). Similarly, the second row 412 indicates that output Q will be a logical 1 (True) and output Q̅ will be a logical 0 (False) when the logical zero level voltages are input to the R and S inputs of the flip-flop and a logical 1 voltage is applied to the D input of the flip-flop when the signal input to the clock input (CLK) transitions from a low level (e.g., 0) to a high level (e.g., 1). The remaining rows may be read in a similar way.

The first flip-flop 304 has in input the CLK signal. Therefore, it may switch and maintain the output logical value at the rising edge of the input signal. The second flip-flop 306 has the inverse of clock signal CLK as input for synchronization purposes because both input signals are generated from the same clock. This implies that the second flip-flop switches and maintains the output logical value at the falling edges of the clock signal, or at the rising edges of the inverse clock signal. When the clock input CLK receives a rising edge (a voltage transition from a low voltage to a high voltage), the present state of the data input is stored in the circuit and the flip-flop output port Q will reflect the current state of the data input D. The Q̅ output will be the inverse state of the Q output state. The input D is connected to the complementary output Q̅ for both flip-flops, thereby allowing for a desired square-wave signal. There is a phase shift between square wave outputs of the two flip-flops that is proportional to the duty cycle (DC) of the input frequency signal. This is because the first flip-flop 304 and the second flip-flop 306 are triggered by the opposite edges of the pulse width modulated signal that is input to the CLK inputs. Since the pulse width modulation has a period T, the rising and falling edges are separated by T*DC, and the two output square waves also have a period of 2*T (since the flip flop divides the input frequency by two) and will be separated by 2*T*DC. Finally, the set input S for the flip-flops is used to set the output to a high state, regardless of the input at the D input and CLK input. The reset input R of the flip-flops is used to reset the output Q to the low state, regardless of the input at the D input and the CLK input. The set and reset state are tied to an appropriate logic voltage level (e.g., low 0 or high 1). The HIL system provides digital outputs that are input to the D. S. and R inputs. However, the D. R. and S ports can be used to set a defined starting condition and to generate sensor anomalies. For example, if one of the sensors degrades, it may give a constant logic level at its output. A constant voltage level at the CLK input may be applied to see how the device under test reacts.

Referring now to FIG. 5, a plan view of a speed sensor 506 with current output speeded to sense wheel speed is shown. Wheel 502 is shown with a plurality of teeth 504. Wheel 502 may rotate in a clockwise direction as indicated by CW. Wheel 502 may also rotate in a counter-clockwise direction as indicated by CCW. Movement of teeth 504 by speed sensor 506 may cause a change in state of the output of speed sensor 506.

Turning now to FIG. 6, sequence 600 shows behavior of the speed sensor emulation circuit 250 when the emulated speed sensor is indicating rotation in a clockwise direction. The sequence shown in FIG. 6 may be generated via the circuit shown in FIG. 3 in cooperation with the method of FIG. 8.

The first plot from the top of FIG. 6 is a plot of a clock signal that is output by the HIL system. The clock signal is a signal with a voltage level that changes as a function of a speed of an emulated rotating device. In another example not shown in FIG. 6, if the emulated rotating device is an engine speed sensor with 60 teeth rotating at 1000 revolutions/minute, the HIL system may generate a pulse width signal cycling between logical 0 and logic 1 with a 50% DC at a frequency of 1000 Hertz. Returning to FIG. 6, the logical 1 and 0 voltage levels are indicated along the vertical axis. The horizontal axis represents time and time increases from the left side of the plot to the right side of the plot.

The second plot from the top of FIG. 6 is a plot that shows the CH A current output of the speed sensor emulation circuit 250. The operating state of output Q of the first flip-flop (e.g., flip-flop A) is equivalent to the output state of CH A, but the output state of output Q of the first flip-flop is a voltage, whereas the output state speed sensor emulation circuit 250 CH A is an electric current. The vertical axis represents electric current based logical level or state for CH A of the speed sensor emulation circuit 250 versus time. The logical 1 and 0 current levels are indicated along the vertical axis. The horizontal axis represents time and time increases from the left side of the plot to the right side of the plot. The set S and reset R inputs of the first flip-flop and the second flip-flop are held at a logical 0 level (not shown) during this sequence.

The third plot from the top of FIG. 6 is a plot that shows the CH B current output of the speed sensor emulation circuit 250. The operating state of output Q of the second flip-flop (e.g., flip-flop B) is equivalent to the output state of CH B, but the output state of output Q of the second flip-flop is a voltage, whereas the output state speed sensor emulation circuit 250 CH B is an electric current. The vertical axis represents electric current based logical level or state for CH B of the speed sensor emulation circuit 250 versus time. The logical 1 and 0 current levels are indicated along the vertical axis. The horizontal axis represents time and time increases from the left side of the plot to the right side of the plot.

At time t0, the clock signal CLK is at a logical 0 level. CH A and CH B are also at logical 0 levels. At time t1, a rising edge 602 of the CLK as indicated by an up arrow shows a transition from a low voltage level (logical 0) to a higher voltage level (logical 1). This causes flip-flop A of the speed sensor emulation circuit 250 to move from a low state (logical 0) to a higher state (logical 1), thereby causing the CH A output of the speed sensor emulation circuit 250 to change the electric current level to change from a lower level (logical 0) to a higher level (logical 1). The CH B output is unchanged since it may change state in response to a falling edge of the CLK signal.

At time t2, a falling edge 604 of the CLK as indicated by a down arrow shows a transition from a higher voltage level (logical 1) to a lower voltage level (logical 0). This causes the second flip-flop of the speed sensor emulation circuit 250 to move from a low state (logical 0) to a higher state (logical 1), thereby causing the CH B output of the speed sensor emulation circuit 250 to change the electric current level to change from a lower level (logical 0) to a higher level (logical 1). The CH A output is unchanged since it may change state in response to a rising edge of the CLK signal. Since the CH A and CH B outputs may change due to different clock edges, a phase delay as indicated by the time shown at 605 develops. The output CH A leads the output CH B in time (time increases from the left side of the plot to the right side of the plot) so this may be indicative of the device being tracked rotating in a clockwise direction.

The duty cycle of the CLK signal may be used to adjust the phase shift as indicated at 605 between CH A and CH B. Additionally, the CLK signal may be used to emulate challenging working conditions of the speed sensor by generating a larger phase shift between CH A and CH B. In other words, the distance 605 may be extended relative to time t1 and toward time t3 to simulate sensor specific conditions. For example, sensitive element of speed sensors (e.g., metal strips in Hall effect sensors) are mounted with a mechanical shift of 90° to ensure best performance. However, due to mechanical constraints, this setup may not always be available, and a non-optimal angle for the metal strips may be used. The non-optimal angle reduces the sensor's capability to detect direction at higher speeds, thereby degrading speed sensor performance. The present invention may emulate non-optimal mechanical angles for the speed sensor by adjusting the phase shift between CH A and CH B. This allows emulation of challenging working conditions of the speed sensor coupled to the controller by setting the phase shift in the boundary range of the allowed mounting angle.

At time t3, another rising edge of the CLK occurs causing the first flip-flop of the speed sensor emulation circuit 250 to move from the higher state (logical 1) to the lower state (logical 0), thereby causing the CH A output of the speed sensor emulation circuit 250 to change the electric current level to change from the higher level (logical 1) to the lower level (logical 0). The CH B output is unchanged since it may change state in response to a falling edge of the CLK signal.

At time t4, a falling edge of the CLK occurs causing the second flip-flop of the speed sensor emulation circuit 250 to move from the higher state (logical 1) to the lower state (logical 0), thereby causing the CH B output of the speed sensor emulation circuit 250 to change the electric current level to change from the higher level (logical 1) to the lower level (logical 0).

Thus, the first and second flip-flops provide an output that is half the frequency of the CLK input signal and two signals are provided with different phases to permit direction of rotation simulation from a single signal (CLK). Further, since the CH A and CH B signals are generated from a lone signal (CLK), the errors in generating two signals that are output of phase with precise timing via the HIL system may be avoided.

Referring now to FIG. 7, sequence 700 shows behavior of the speed sensor emulation circuit 250 when the emulated speed sensor indicates a change in rotational direction. The sequence shown in FIG. 7 may be generated via the circuit shown in FIG. 3 in cooperation with the method of FIG. 8.

The first plot from the top of FIG. 7 is a plot of a clock signal that is output by the HIL system. The clock signal is a signal with a voltage level that changes as a function of a speed of an emulated rotating device. In this example, the HIL system generates a pulse width signal cycling between logical 0 and logic 1 with a 50% DC. The logical 1 and 0 voltage levels are indicated along the vertical axis. The horizontal axis represents time and time increases from the left side of the plot to the right side of the plot.

The second plot from the top of FIG. 7 is a plot that shows the CH A current output of the speed sensor emulation circuit 250. The vertical axis represents electric current based logical level or state for CH A of the speed sensor emulation circuit 250 versus time. The logical 1 and 0 current levels are indicated along the vertical axis. The horizontal axis represents time and time increases from the left side of the plot to the right side of the plot.

The third plot from the top of FIG. 7 is a plot that shows the CH B current output of the speed sensor emulation circuit 250. The vertical axis represents electric current based logical level or state for CH B of the speed sensor emulation circuit 250 versus time. The logical 1 and 0 current levels are indicated along the vertical axis. The horizontal axis represents time and time increases from the left side of the plot to the right side of the plot.

The fourth plot from the top of FIG. 7 is a plot that shows the set input (SA) of flip-flop A of the speed sensor emulation circuit 250. The vertical axis shows the logical 1 and 0 voltage levels for the set input of flip-flop A. The horizontal axis represents time and time increases from the left side of the plot to the right side of the plot.

The fifth plot from the top of FIG. 7 is a plot that shows the reset input (RA) of flip-flop A of the speed sensor emulation circuit 250. The vertical axis shows the logical 1 and 0 voltage levels for the reset input of flip-flop A. The horizontal axis represents time and time increases from the left side of the plot to the right side of the plot.

The sixth plot from the top of FIG. 7 is a plot that shows the set input (SB) of flip-flop B of the speed sensor emulation circuit 250. The vertical axis shows the logical 1 and 0 voltage levels for the set input of flip-flop B. The horizontal axis represents time and time increases from the left side of the plot to the right side of the plot.

The seventh plot from the top of FIG. 7 is a plot that shows the reset input (RB) of flip-flop B of the speed sensor emulation circuit 250. The vertical axis shows the logical 1 and 0 voltage levels for the reset input of flip-flop B. The horizontal axis represents time and time increases from the left side of the plot to the right side of the plot.

The speed sensor emulation circuit 250 includes two flip-flops that are sensitive to opposite edges of the CLK signal. For a CLK signal with a period of T seconds, CH A and CH B have a phase shift of 2·T·DC, where DC is the duty cycle. The output of the speed sensor is dependent on orientation of the speed sensor. When the speed sensor is oriented in a first way, the controller 144 detects direction of rotation of a rotating device based on the logical level of CH B in the time instant CH A has a rising edge (e.g. instant CH A transitions from a low level to a high level). Therefore, there are two possibilities: if CH B is high, clockwise rotation, if CH B is low, counter clockwise rotation. The opposite may be the case if the speed sensor is oriented in a different way. Nevertheless, it is important to start from a known initial condition of the flip-flop internal states and outputs Q and Q̅ to correctly emulate the inversion of rotational direction. Therefore, set and reset input ports of the two flip-flops may be controlled.

At time t10, the clock signal CLK, set input for the first flip-flop (e.g., flip-flop A), reset input for the first flip-flop (e.g., flip-flop A), set input for the second flip-flop (e.g., flip-flop BA), reset input for the second flip-flop (e.g., flip-flop B), receive logical 0 levels. CH A and CH B are also at logical 0 levels.

At time t11, a rising edge 702 of the CLK as indicated by an up arrow shows a transition from a low voltage level (logical 0) to a higher voltage level (logical 1). This causes the first flip-flop of the speed sensor emulation circuit 250 to move from a low state (logical 0) to a higher state (logical 1), thereby causing the CH A output of the speed sensor emulation circuit 250 to change the electric current level to change from a lower level (logical 0) to a higher level (logical 1). The CH B output is unchanged since it may change state in response to a falling edge of the CLK signal. The set input for the first flip-flop, reset input for the first flip-flop, set input for the second flip-flop, and the reset input for the second flip-flop to remain at logical 0 levels.

At time t12, a falling edge 704 of the CLK as indicated by a down arrow shows a transition from a higher voltage level (logical 1) to a lower voltage level (logical 0). This causes the second flip-flop of the speed sensor emulation circuit 250 to move from a low state (logical 0) to a higher state (logical 1), thereby causing the CH B output of the speed sensor emulation circuit 250 to change the electric current level to change from a lower level (logical 0) to a higher level (logical 1). The CH A output is unchanged since it may change state in response to a rising edge of the CLK signal. The output CH A leads the output CH B in time (time increases from the left side of the plot to the right side of the plot) so this may be indicative of the device being tracked rotating in a clockwise direction.

At time t13, the CLK signal duty cycle is reduced to zero to prepare for emulating a change in rotational direction of the emulated rotating device (e.g., tooth wheel, etc.), CH A is at a high level, and CH B transitions from the low level to the high level. The set and reset inputs of each flip-flop are at lower levels.

At time t14, the set input of the first flip-flop and the reset input of the second flip-flow are transitioned from the low level to the high level. The reset input of the first flip-flop and the set input of the second flip-flop are maintained at the low level. During the time interval between t14 and t15 as shown at 706, the internal states of the first and second flip-flops are forced to known states. In particular, the output of the first flip-flop drives CH A to a high level and the output of the second flip-flop drives CH B to a low level while CLK is low.

At time t15, the duty cycle of the CLK signal changes from zero to a non-zero value so that CH A switches from the higher level to the lower level. CH B is unchanged and set A and reset B signals transition from higher levels to lower levels.

At time t16, the CLK signal transitions to a lower level and the falling edge of the CLK signal causes CH B to transition from a low state to a high state. CH A is unchanged and the set and reset inputs of the two flip-flops remain at lower levels. Thus, the rising edge of CH B now leads the rising edge of CH A so as to indicate a change in direction of the emulated rotating device.

Thus, the present system may simulate a change in rotational direction by applying logical one (e.g., high level) to S and R inputs of the first and second flip-flops of the speed sensor emulation circuit 250. The HIL system may determine whether or not the controller senses the change in rotational direction as it may be expected to do so.

Referring to FIG. 8, a state machine diagram of a method for generating signals to simulate a speed sensor with current output of a HIL system is shown. The state machine and method of FIG. 8 may be at least partially implemented as executable instructions stored in controller memory in the systems of FIGS. 1-3. Further, the state machine and method of FIG. 8 may include actions taken in the physical world to transform operating states of the system of FIGS. 1-3.

Block diagram 800 includes a state machine 802, a pulse width modulation generator 804, a speed sensor emulation circuit 250, and an analog input block 806. The state machine 802 may be implemented via controller software and it provides two outputs (e.g. duty_cycle and period) to pulse width modulation generator 804. State machine 802 also supplies digital outputs Set A, Set B. Reset A, and Reset B to speed sensor emulation circuit 250. The speed sensor emulation circuit 250 provides output CH A and CH B to inputs of state machine 802. State machine 802 also includes inputs for frequency of rotation for the emulated device (e.g., a wheel with teeth), frequency sign (indicates direction of rotation), and threshold parameters. A more detailed description of state machine 802 is provided in the description of FIG. 9.

Referring now to FIG. 9, a diagram 900 of state machine 802 is shown. The state machine of FIG. 9 may operate in cooperation with the system of FIGS. 1-3 to adjust operating states of the system of FIGS. 1-3 in the real world. The method of FIG. 9 may be at least partially implemented as executable instructions stored in controller memory in the systems of FIGS. 1-3.

State machine 802 includes four states including standstill, moving. Start_fwd, and Start_rev. The state machine is entered via initial condition Init, which calls the toStandstill function. The states may be entered when specific conditions are met, and actions may be triggered during a transition from one state to another state. The arrows between the states and their conditional requirements (e.g., square brackets) and actions (e.g., curly brackets) are used to show conditions and actions when transitioning from one state to another state. State machine 802 includes four functions 902-908. The to_Standstill function 902 is called upon during initialization. The to_Moving function 904 may be performed when moving to moving state 926. The to_Forward function 906 may be performed when moving to Start_fwd state 924. The to_Reverse function 908 may be performed when moving to Start_rev state 920. The actions in these functions may be performed during transitions between the states. For example, inputs to the speed sensor emulation circuit 250 may be set to Reset A=false, Reset B=false, Set A=false, and Set B=false when moving to moving state 926.

For example, arrow 910 shows a transitional path from Start_rev state 920 to moving state 926. This transition may occur when CH A=1 and CH B=0. The actions of making the set input to the first flip-flop or flip-flop A to false, making the set input to the second flip-flop or flip-flop B to false, making the reset input to the first flip-flop false, and making the reset input to the second flip-flop false are indicates along the side of arrow 910.

The HIL system user may request a speed of a wheel or other rotating device for the HIL system to emulate as input to the speed sensor emulation circuit. If the absolute value of the state machine input frequency value exceeds the threshold parameter threshold_move the state machine state changes to Start_rev (reverse) or Start_fwd (forward) depending on the frequency sign. The state machine remains in one of these states until feedback from CH A and Ch B enables the transition to the moving state. Once in the moving state, the state machine input frequency is converted to a corresponding period and the duty cycle is set to duty_mab_pct value. For example, duty_mab_pct=50% means that CH A and CH B are shifted by 90°. Frequency and duty cycle are then sent to the PWM generator that creates the clock control signal for the speed sensor emulation circuit as shown in FIG. 8.

The state machine may transition to the standstill state when the absolute value of the input frequency decreases below the threshold threshold_stop. Note that threshold_move is set to a value that is greater than threshold_stop so that a hysteresis mechanism preventing the state machine from bouncing back and forth between standstill and moving states when the input frequency is near one of the two thresholds.

During transitions from one state to another, one of the following functions is called: toReverse( ), toForward( ), toMoving( ), toStandstill( ). Each one of these functions may assign a value to the set/reset signal for the flip-flop state on the speed sensor emulation circuit 250, providing a correct initial condition (a well know and defined state) before the clock signal starts toggling. Additionally, there are two transitions respectively from the moving state to Start_rev and Start_fwd that may be accomplished without passing through the standstill state. These transitions cover the case in which the input frequency changes sign without decreasing in absolute value below threshold_stop (this may happen if the threshold is set small and the integration step is large).

The state machine 802 may also be adapted to output specific values to the set and reset inputs of the speed sensor emulation circuit 250 to simulate speed sensor degradation. For example, a connection between speed sensor output on CH A and battery voltage may be emulated via adjusting the reset A input to the speed sensor emulation circuit 250 as true or a logical one.

Thus, the state machine of FIGS. 8 and 9 may generate a clock signal CLK, set inputs, and reset inputs to a speed sensor emulation circuit. The state machine may simulate forward and reverse rotational directions as well.

The method of FIGS. 8 and 9 provides for a method for simulating a speed sensor with current output, comprising: providing a signal to the first memory device clock input of and an inverse of the signal to a second memory device clock input; and supplying the first memory device A output to a first voltage controlled current source and a second memory device output to a second voltage controlled current source. In a first example, the method includes where the signal is supplied via a hardware-in-the-loop system. In a second example that may include the first example, the method includes where the first voltage controlled current source and the second voltage controlled current source are coupled to a device under test. In a third example that may include one or both of the first and second examples, the method further comprises generating the signal via the hardware-in-the loop system. In a fourth example that may include one or more of the first through third examples, the method further comprises electrically coupling S and R inputs of the first flip-flop to the hardware-in-the-loop system. In a fifth example that may include one or more of the first through fourth examples, the method further comprises electrically coupling S and R inputs of the second flip-flop to the hardware-in-the-loop system. In a sixth example that may include one or more of the first through fifth examples, the method further comprises simulating a change in direction of a device via applying a logical true input to the S input of the first flip-flop and the R input of the second flip-flop.

In another representation the method of FIGS. 8 and 9 provides for a method for simulating a speed sensor with current output, comprising: providing a signal to a first memory device clock input of and an inverse of the signal to a second memory device clock input; and supplying a first memory device first output to a first voltage controlled current source and a second memory device first output to a second voltage controlled current source, where the first memory device and the second memory devices are D flip-flops, and where a Q̅ output of the first memory device is wired (e.g., directly electrically coupled) to a D input of the first memory device. The method further comprises adjusting signal levels provided to S and R inputs of the first memory device via a hardware-in-the-loop system.

Referring now to FIG. 10, an example sequence that may be generated via the system of FIGS. 1-3 in cooperation with the method of FIGS. 8 and 9 is shown. The sequence of FIG. 10 emulates output CH B being shorted to ground. The vertical and horizontal axes for the plots of FIG. 10 are the same as those shown in FIG. 7. Therefore, for the sake of brevity, the description of each plot is omitted.

In this example, the sequence starts at time t20. All signals are at their lower levels and emulation of a ground short circuit to CH B is not shown.

At time t21, the CLK transitions from a low level to a high level 1002 and the CH A output transitions from a low level to a high level. The set and reset inputs to the speed sensor emulation circuit 250 are at low levels.

At time t22, a CH B short to ground is emulated via holding CH B at a high level. This is accomplished by applying a high level (e.g., logical 1) to the set input of the second flip-flop in the speed sensor emulation circuit 250. The CLK signal transitions to a low level as indicated at 1004.

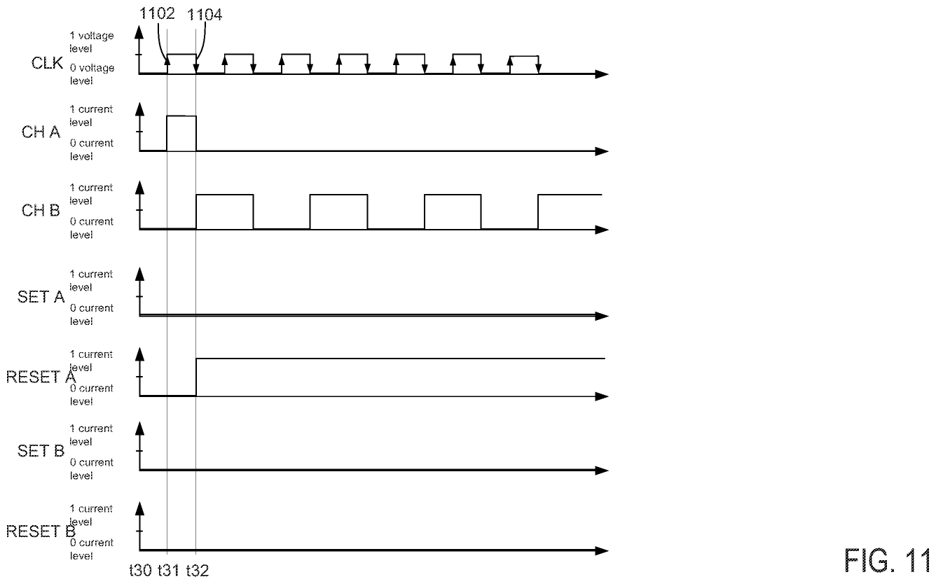

Referring now to FIG. 11, an example sequence that may be generated via the system of FIGS. 1-3 in cooperation with the method of FIGS. 8 and 9 is shown. The sequence of FIG. 11 emulates output CH A being shorted to battery voltage. The vertical and horizontal axes for the plots of FIG. 11 are the same as those shown in FIG. 7. Therefore, for the sake of brevity, the description of each plot is omitted.

In this example, the sequence starts at time t30. All signals are at their lower levels and emulation of a battery voltage short circuit to CH A is not shown.

At time t31, the CLK transitions from a low level to a high level as indicated at 1102 and the CH A output transitions from a low level to a high level. The set and reset inputs to the speed sensor emulation circuit 250 are at low levels.

At time t32, a CH A short to battery voltage is emulated via holding CH A at a high level. This is accomplished by applying a high level (e.g., logical 1) to the reset input of the first flip-flop (in the speed sensor emulation circuit 250).

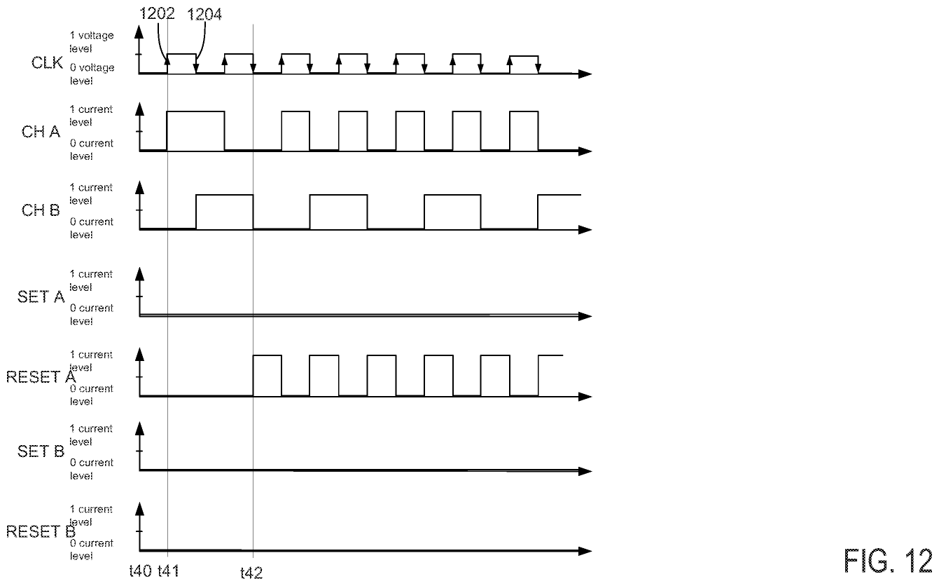

Referring now to FIG. 12, an example sequence that may be generated via the system of FIGS. 1-3 in cooperation with the method of FIGS. 8 and 9 is shown. The sequence of FIG. 12 emulates intermittent degradation of a speed sensor. The vertical and horizontal axes for the plots of FIG. 12 are the same as those shown in FIG. 7. Therefore, for the sake of brevity, the description of each plot is omitted.

In this example, the sequence starts at time t40. All signals are at their lower levels and emulation of intermittent speed sensor degradation is not shown.

At time t41, the CLK transitions from a low level to a high level as indicated at 1202 and the CH A output transitions from a low level to a high level. The set and reset inputs to the speed sensor emulation circuit 250 are at low levels.

At time t42, intermittent degradation of CH A output is emulated via switching the reset input of the first flip-flop of the speed sensor emulation circuit 250. This causes the CH A output to switch with rising and falling edges of the CLK signal as the CLK signal moves between the high level and the low level.

The present description illustrates how two D flip-flops (e.g., memory devices), two voltage controlled current sources, and executable instructions stored in non-transitory memory may be a basis for emulating a speed sensor with current output. However, it will be appreciated that J-K flip-flops, reset/set flip-flops, binary storage devices, and other memory devices may be arranged and configured to simulate a speed sensor with current output without departing from the scope or intent of the present description.

It will be appreciated that the configurations and routines disclosed herein are exemplary in nature, and that these specific examples are not to be considered in a limiting sense, because numerous variations are possible. For example, the above technology can be applied to powertrains that include different types of propulsion sources including different types of electric machines and transmissions. The subject matter of the present disclosure includes all novel and non-obvious combinations and sub-combinations of the various systems and configurations, and other features, functions, and/or properties disclosed herein.

The following claims particularly point out certain combinations and sub-combinations regarded as novel and non-obvious. These claims may refer to “an” element or “a first” element or the equivalent thereof. Such claims may be understood to include incorporation of one or more such elements, neither requiring nor excluding two or more such elements. Other combinations and sub-combinations of the disclosed features, functions, elements, and/or properties may be claimed through amendment of the present claims or through presentation of new claims in this or a related application. Such claims, whether broader, narrower, equal, or different in scope to the original claims, also are regarded as included within the subject matter of the present disclosure.

1. A sensor emulation system, comprising:
a first memory device configured to receive a signal at an input of the first memory device and provide a first voltage output to a first voltage controlled current source; and
a second memory device configured to receive an inverse of the signal at an input of the second memory device and provide a second voltage output to a second voltage controlled current source.

2. The sensor emulation system of claim 1, where the first memory device and the second memory device are D flip-flops, where the input of the first memory device is a clock input, and where the input to the second memory device is a clock input.

3. The sensor emulation system of claim 1, where the first memory device includes a first D input and a first Q̅ output.

4. The sensor emulation system of claim 3, where the second memory device includes a second D input and a second Q̅ output.

5. The sensor emulation system of claim 4, where the first Q̅ output is electrically coupled to the first D input.

6. The sensor emulation system of claim 5, where the second Q̅ output is electrically coupled to the second D input.

7. The sensor emulation system of claim 1, further comprising a first S input and a first R input on the first memory device and a second S input and a second R input on the second memory device.

8. The sensor emulation system of claim 7, where a hardware-in-the-loop system generates the signal and includes outputs coupled to the first S input, the first R input, the second S input, and the second R input.

9. A method for simulating a speed sensor with current output, comprising:
providing a signal to a first memory device input and an inverse of the signal to a second memory device input; and
supplying a first memory device first output to a first voltage controlled current source and a second memory device first output to a second voltage controlled current source.

10. The method of claim 9, where the signal is supplied via a hardware-in-the-loop system, where the first memory device input is a first clock input, and where the second memory device input is a second clock input.

11. The method of claim 10, where the first voltage controlled current source and the second voltage controlled current source are coupled to a device under test.

12. The method of claim 11, further comprising generating the signal via the hardware-in-the loop system.

13. The method of claim 12, further comprising electrically coupling a S input of a first memory device and a R input of the first flip-flop to the hardware-in-the-loop system.

14. The method of claim 13, further comprising electrically coupling a S input of a second memory device and a R input of the second memory device to the hardware-in-the-loop system.

15. The method of claim 14, further comprising simulating a change in direction of a device via applying a logical true input to the S input of the first memory device and the R input of the second memory device.

16. A hardware-in-the-loop (HIL) system with sensor emulation, comprising:
a HIL system coupled to a device under test;
a first flip-flop configured to receive a signal from the HIL system at a clock input of the first flip-flop and provide a first voltage output to a first voltage controlled current source; and
a second flip-flop configured to receive an inverse of the signal at a clock input of the second flip-flop and provide a second voltage output to a second voltage controlled current source.

17. The HIL system of claim 16, further comprising a device under test coupled to the system.

18. The HIL system of claim 17, further comprising a first digital output of the HIL system generating the signal and additional digital outputs of the HIL system generating output to a first flip-flop S input, a first flip-flop R input, a second flip-flop S input, and a second flip-flop R input.

19. The HIL system of claim 18, where the first voltage controlled current source is coupled to the device under test.

20. The HIL system of claim 19, where the second voltage controlled current source is coupled to the device under test.
